(19) United States
(12) Patent Application Publication
(10) Pub. No.: US 2006/0062059 A1
(43) Pub. Date: Mar. 23, 2006

(54) Method and apparatus for meta-data storage and retrieval

(76) Inventors: Alfonso Martinez Smith, Algonquin, IL (US); Jianjun Fang, Long Grove, IL (US); Bhavan R. Gandhi, Vernon Hills, IL (US); Dongge Li, Hoffman Estates, IL (US)

Correspondence Address: MOTOROLA, INC., 1303 EAST ALGONQUIN ROAD, IL01/3RD, SCHAUMBURG, IL, 60196, US

(21) Appl. No.: 10/945,414

(22) Filed: Sep. 20, 2004

(51) Int. Cl. G11C 7/00

(52) U.S. Cl. 365/199

(57) ABSTRACT

Meta-data retrieved externally is determined to be relevant to the creation of an electronic programming guide (EPG) or relevant to a user's preferred programs. The meta-data is stored locally if it is determined that it is relevant to the creation of the EPG or if it is relevant to the user's preferred programs. All other meta-data is discarded. When a user requests meta-data, an attempt is made to retrieve the data from a local database, and if the attempt fails, then the meta-data is obtained from an external source.

### FIELD OF THE INVENTION

The present invention relates generally to meta-data, and in particular, to a method and apparatus for storing and retrieving such meta-data.

### BACKGROUND OF THE INVENTION

Recently proposals have been made to broadcast digital video and television to mobile users. These proposals includes the broadcasting of data to the mobile user that adequately describes the digital content, and when it will be available. Such meta-data includes information such as program title, genre, rating, cost, cast of characters, parental rating, available languages, content links, . . . , etc.

Existing techniques for meta-data storage and transmission to remote/mobile units have the meta-data stored inside “containers” that are constantly updated and broadcast via “carousels” to the mobile client. A user's mobile device will present the user with an Electronic Program Guide (EPG) that is assembled from the top level of the meta-data hierarchy carried in the containers. When the user makes a selection from the EPG, the mobile device must access the remaining meta-data pertaining to that program selection.

In order to make the remaining meta-data readily available, current systems are faced with two options. The first option is to decode all the container information provided to the remote unit and store it locally. This option is not viable for mobile devices with restricted storage capabilities. The second option is to decode only the part of the container holding EPG-specific information (e.g., available programs) and, if the user chooses to access a particular program's meta-data, to retrieve the data when the container containing the data cycles around the carousel. This involves added latency while waiting for the container and the need to re-decode each container's header. Therefore a need exists for a method and apparatus for meta-data storage and retrieval that eliminates the need to store large quantities of meta-data, yet in most cases allows a user fast access times to the meta-data.

### BRIEF DESCRIPTION OF THE DRAWINGS

FIG. 1 is a block diagram of a meta-data container.

FIG. 2 is a block diagram of a meta-data carousel.

FIG. 3 is a block diagram of a communication system showing transmission of meta-data to a remote unit.

FIG. 4 is a more-detailed block diagram of a remote unit receiving and storing meta-data.

FIG. 5 is a flow chart showing operation of the remote unit of FIG. 4.

FIG. 6 is a flow chart showing operation of the remote unit of FIG. 4.

### DETAILED DESCRIPTION OF THE DRAWINGS

To address the above-mentioned need a method and apparatus for storing and retrieving meta-data is provided herein. Meta-data retrieved externally is determined to be relevant to the creation of an electronic programming guide (EPG) or relevant to a user's preferences (e.g., preferred programs). The meta-data is stored locally if it is determined that it is relevant to the creation of the EPG or if it is relevant to the user's preferred programs. All other meta-data is discarded. When a user requests meta-data, an attempt is made to retrieve the data from a local database, and if the attempt fails, then the meta-data is obtained from an external source.

The present invention encompasses a method for meta-data storage. The method comprises the steps of receiving meta-data from an external source, determining if the meta-data is essential to a formation of an electronic programming guide (EPG), and determining if the meta-data is relevant to a user's preferred programs. Meta-data that is essential to the formation of the EPG and the meta-data that is relevant to the user's preferred programs is stored, with all other meta-data being discarded.

The present invention additionally encompasses a method comprising the steps of retrieving a request to supply meta-data to a user, and determining if the meta-data resides in a local database. The local database comprises meta-data that is relevant to the user's preferred programs and meta-data that is essential to a formation of an electronic programming guide (EPG). The meta-data is retrieved from the local database when the meta-data resides in the local database otherwise the meta-data is retrieved from an external database.

The present invention additionally encompasses an apparatus comprising a receiver having meta-data received from an external source as an input. The apparatus additionally comprises logic circuitry determining if the meta-data is essential to a formation of an electronic programming guide (EPG) or relevant to a user's preferred programs. Finally, the apparatus comprises a database storing the meta-data that is essential to the formation of the EPG and the meta-data that is relevant to the user's preferred programs.

The present invention additionally encompasses an apparatus comprising logic circuitry retrieving a request to supply meta-data to a user and determining if the meta-data resides in a local database. The local database comprises meta-data that is relevant to the user's preferred programs and meta-data that is essential to a formation of an electronic programming guide (EPG). The logic circuitry, when requested, retrieves the meta-data from the local database when the meta-data resides in the local database otherwise retrieves the meta-data from an external database.

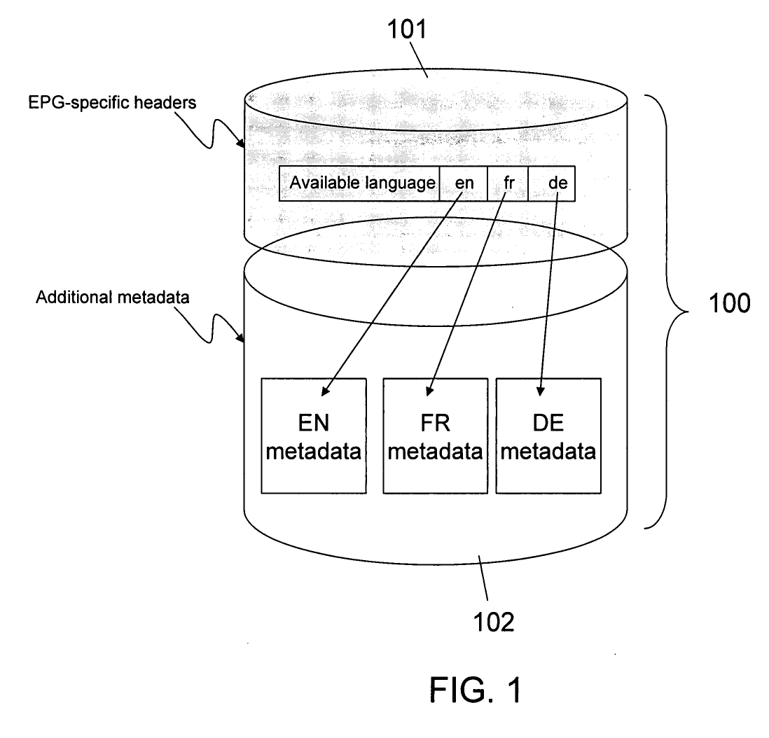

Turning now to the drawings, wherein like numerals designate like components, FIG. 1 is a block diagram of meta-data container 100. Container 100 is preferably hard disk storage storing hierarchically arranged meta-data. As known in the art, meta-data comprises data about data. More particularly, in data processing, meta-data is definitional data that provides information about or documentation of other data managed within an application or environment. For example, meta-data would document data about data elements or attributes, (name, size, data type, etc) and data about records or data structures (length, fields, columns, etc) and data about data (where it is located, how it is associated, ownership, etc.). Meta-data may include descriptive information about the context, quality and condition, or characteristics of the data.

Container 100 comprises portion 101 holding meta-data specific to the generation of an EPG. Such data includes, but is not limited to EPG specific headers including program names, times of programs, lengths of programs, genres, available languages, parental rating, cost (if pay-per-view), . . . , etc. Container 100 also comprises second portion 102 carrying meta-data not essential to the generation of an EPG. Such data includes, but is not limited to specific details on programs, actors appearing within programs, rating of the programs, and textual/image/video summaries of the programs. As is evident, FIG. 1 illustrates an example of EPG-specific meta-data (available languages) and more-detailed non EPG meta-data (English, French, and German meta-data describing specific non EPG program attributes).

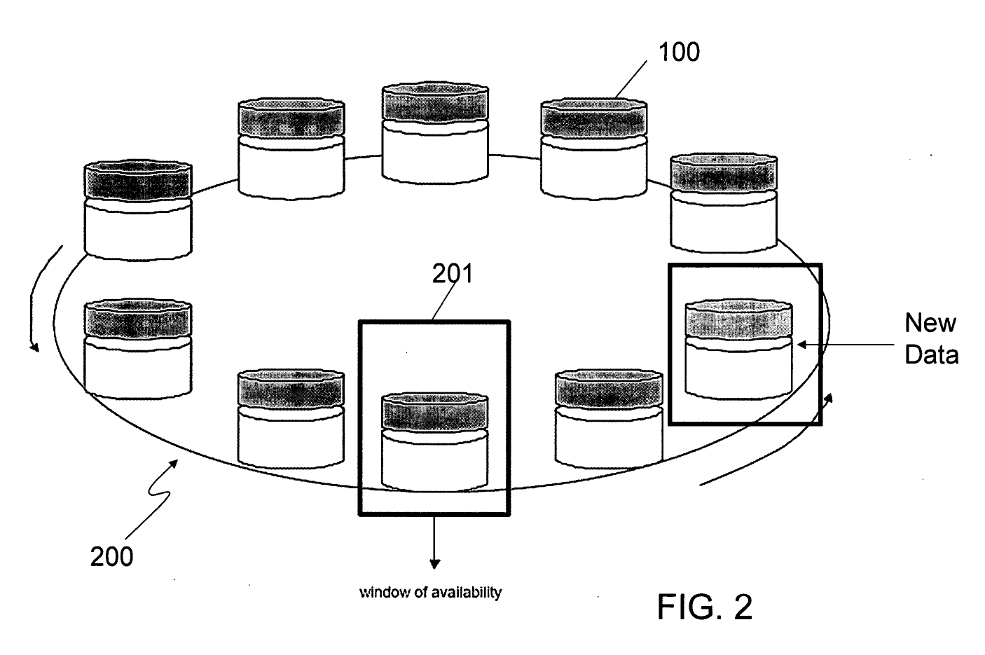

As described above, meta-data storage is typically arranged in a carousel fashion, with specific containers 100 making up the carousel. Such a carousel system of meta-data storage is described in detail in the ISO/IEC International Standard 13818-6: MPEG-2 Digital Storage Media Command & Control, Chapter 11. July 1996, which is incorporated by reference herein. Such a carousel 200 is shown in FIG. 2. As shown, a plurality of containers 100 make up carousel 200. As carousel 200 rotates, each container's data is provided to users when it reaches point, or window of availability 201. When a specific container 100 reaches point 201, its contents will be broadcast to all users receiving meta-data. Each container is marked with an ID number and a version number. When information in the container needs to be updated, a new container, with the same ID number but different version number, is placed on the carousel, and the old container is deleted.

It should be noted that each container 100 within carousel 200 will not comprise the same data. More particularly, containers are populated with fragments of meta-data of a limited size, appropriate to the pre-defined maximum size of the container, the relevance or hierarchical level of the meta-data, and with grouping representative of the programs they are describing. To expand on this, all containers carry up to a maximum allowed amount of meta-data. Certain containers carry meta-data providing more detail than that in other containers, which is made available to users upon request. The union of the meta-data of all related containers can be thought of as a hierarchical structure that can be represented by a tree data structure, where the meta-data found in levels closer to the root of the tree is essential or more relevant to the description of the program than the meta-data found at the lower levels of the tree. Finally, all meta-data carried in a container is pertinent to the same program, rather than to a multiplicity of programs.

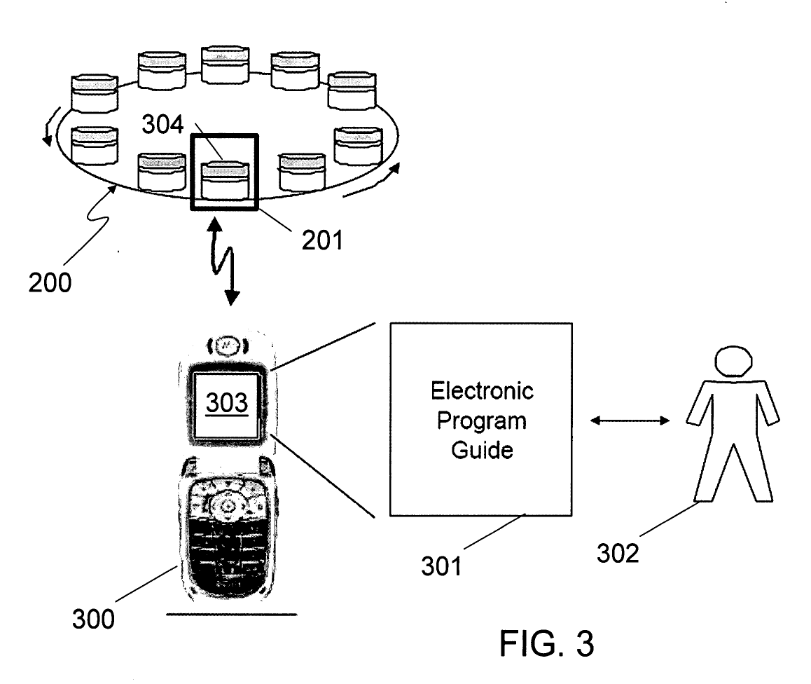

As discussed, when a particular container 100 reaches point 201, its contents will be broadcasted to devices requiring meta-data. This is illustrated in FIG. 3. As shown, container 304 has reached point 201, and will have its contents broadcast via over-the-air transmission to remote device 300. In this particular example, remote device 300 comprises a cellular telephone that is capable of broadcasting digital content, however device 300 may comprise other remote devices such as, but not limited to personal digital assistants and laptop computers with wireless communications capabilities. Device 300 will utilize the meta-data to construct EPG 301 for viewing on display 303 by user 302.

In order to make the meta-data readily available, prior-art systems are faced with two options. The first option is to decode all containers provided to remote unit 300 and store the data locally. As discussed, this option is not viable for mobile devices with restricted storage capabilities. The second option is to decode only the part of the container holding EPG-specific information and, if the user chooses additional data, retrieve it from carousel 200. The retrieval may require remote unit 300 to wait for a particular container to cycle around the carousel. This adds latency while waiting for the container.

In order to address these issues, in the preferred embodiment of the present invention device 300 will decode all meta-data provided to it. All meta-data needed to create EPG 301 will be decoded and stored, however, meta-data not essential to the generation of an EPG will be selectively stored only when deemed relevant to the user's preferred programs and/or viewing habits. This is accomplished by equipping device 300 with a database containing user preferred programs and/or capabilities. The user preferred programs may be input into device 300 by the user and may comprise such programs having a preferred genre and sub-genre (e.g., drama / war-time movies), programs having preferred actors, and programs having a preferred language (e.g., Spanish). User capabilities, on the other hand, comprise such things as a device's ability to play certain media, a device's ability to support interactive digital TV services, a device's memory capabilities to cache programs for delayed viewing, . . . , etc.

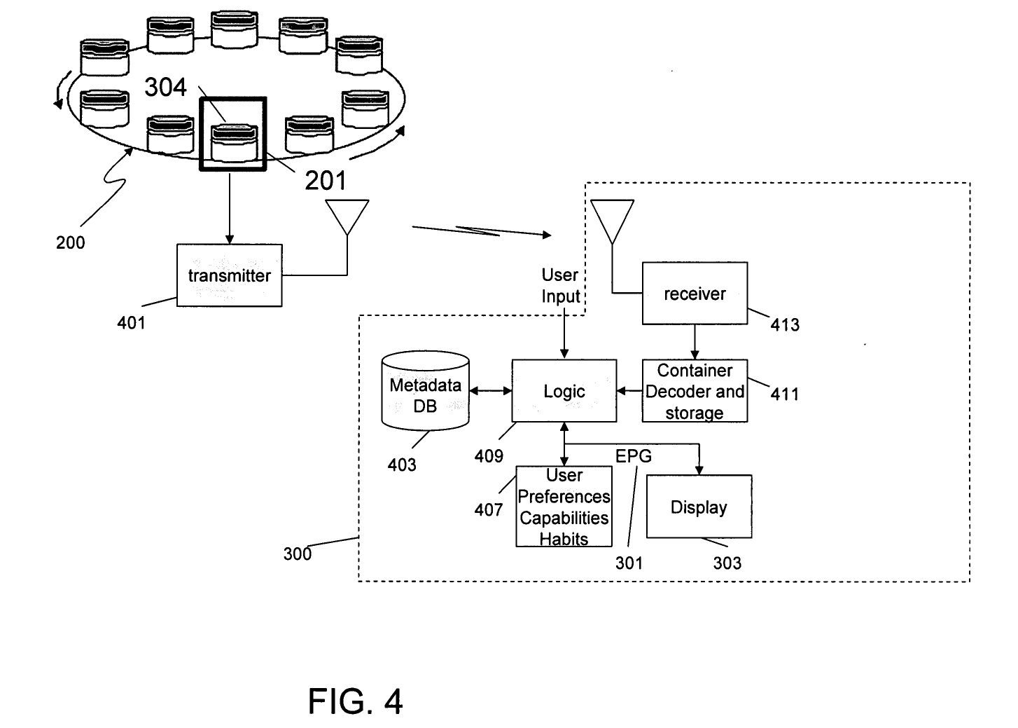

FIG. 4 is a block diagram showing a more-detailed view of a remote unit receiving and storing specific meta-data. Remote unit 300 preferably comprises logic circuitry 409, display 303, user preference/capability database 407, receiver 413, decoder 411, and database 403. Logic circuitry 409 is preferably a microprocessor/controller such as a PowerPC available from Motorola, Inc., while databases 407 and 403 are preferably solid state storage such as on-board memory or removable storage media, on which a software (e.g., SQL) database is operating. Receiver 413 comprises a standard over-the-air receiver utilizing an appropriate transmission/reception protocol capable of receiving IP datacast streams. For example, if remote unit 300 comprises a cellular telephone employing a particular cellular system protocol, receiver 413 would comprise a standard cellular telephone receiver employing the particular protocol, with the protocol being capable of handling IP datacast streams. Thus, for example, if remote unit 300 comprises a cellular telephone employing the GPRS system protocol, receiver 413 would comprise a standard GPRS cellular telephone receiver capable of IP datacast reception.

When a particular container 304 reaches point 201, the contents of container 304 are transmitted to remote unit 300 via transmitter 401. The meta-data transmitted to remote unit 300 is received by receiver 413 and decoded by container decoder 411. As is known in the art, meta-data is typically encoded to provide efficient transmission of the data. More particularly, meta-data is encoded using a binary format that signals, within a binary bit-stream, the command (ADD, DELETE, RESET), context (detailed path location within the tree data structure representing the aggregated meta-data of a program), and payload (the actual fragments of meta-data being processed). This binary format is used to represent the less efficient but more expressive textual representation of meta-data commonly provided by the extensible markup language (XML).

Once decoded by decoder 411, all data is stored within decoder 411. Logic circuitry 409 analyzes the data and stores data necessary to create EPG 301 in meta-data database 403. Logic circuitry 409 then accesses database 407 to retrieve the user's preferred programs and/or capabilities and compares them to the meta-data received and stored in decoder 411. If the meta-data stored in container decoder 411 matches the user preferred programs and/or capabilities, the data that matches is then stored by logic circuitry 409 in database 403. Thus, all meta-data necessary for creation of an EPG is stored, with all other meta-data being selectively stored. This greatly reduces the amount of storage needed within remote unit 300.

Logic unit 409 provides an EPG to the user via display 303. If the user requests more information on any particular program, the data is accessed via logic circuitry 409, first through database 403, and if necessary, by accessing a container containing the data when the container cycles around the carousel. As is evident, the user is likely to choose to access data from among the data stored within internal database 403. If, however, the data is not contained within local database 403, logic circuitry 409 then attempts to obtain the data from the external database (i.e., carousel 200). As discussed above, the retrieval of data from carousel 200 may take an appreciable amount of time.

If the user's choice does not fall under the personal preferences defined in the user preferences database 407, the logic unit 409 may write information about the user's choice into the user preferences database 407. Thus, database 407 may be populated by analyzing meta-data currently accessed by the user, and storing such meta-data. This may be done automatically of through user prompting and acknowledgment, with the former occurring without user knowledge and the latter occurring through a confirmation process presented on display 303.

Furthermore, the meta-data information that is stored in the meta-data database 403 includes time stamping information to indicate the period of validity of the meta-data. If the period of validity is exceeded and the information has not been retrieved from the meta-data database 403, as verified by the logic unit 409, the logic unit deletes the meta-data from the meta-data database 403 as it will not be used in response to a user choice and therefore, can be removed to free up space in the database.

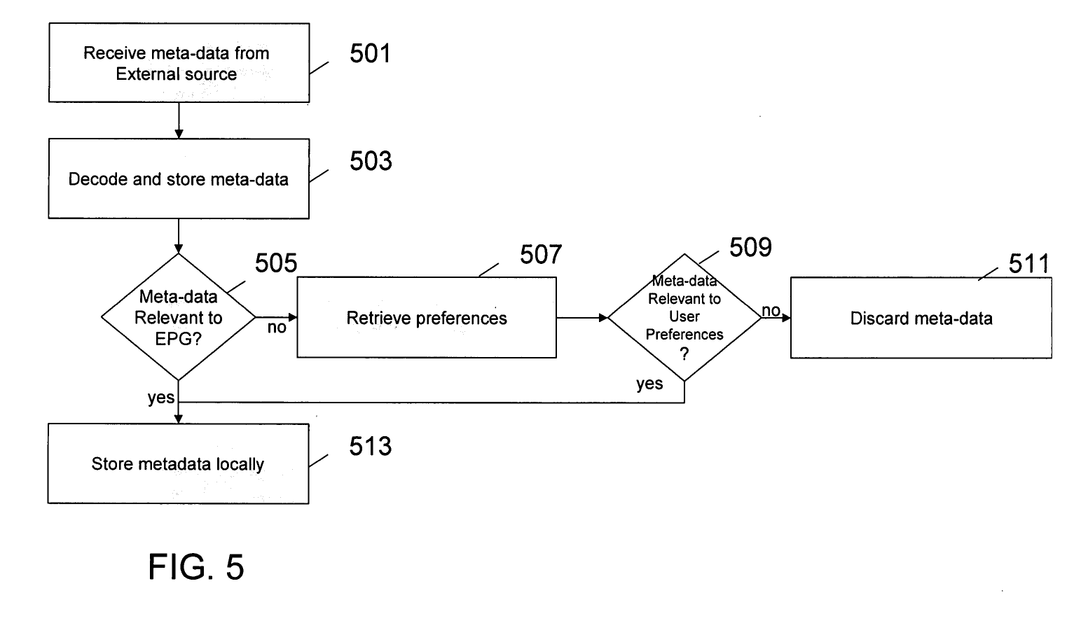

FIG. 5 is a flow chart showing operation of the remote unit of FIG. 4 for storing meta-data. The logic flow begins at step 501 where meta-data is received from an external over-the-air source by receiver 413. At step 503 the meta-data is decoded and stored via decoder 411. At step 505 logic circuitry 409 determines if the meta-data is relevant to the creation of an EPG. In particular, at step 505 logic circuitry 409 determines if the meta-data comprises such meta-data as program names, meta-data of program times, meta-data of program lengths, meta-data of program genres, meta-data of program languages, meta-data of parental ratings, and meta-data of program cost, . . . , etc. If, at step 505 it is determined that the meta-data is relevant to the creation of an EPG, then the logic flow continues to step 513 where the meta-data is stored locally in database 403. If, however, it is determined at step 505 that the meta-data is not relevant to the creation of an EPG, the logic flow continues to step 507. At step 507 logic circuitry 409 obtains user preferred programs (e.g., programs with the user's preferred genre and sub-genre, programs with the user's preferred actors, viewing behaviors, and programs with the user's preferred language, . . . , etc.) from database 407 and then determines if the meta-data is relevant to the user's preferred programs (step 509). If, at step 509 it is determined that the meta-data is relevant to the user's preferred programs, then the meta-data is stored (step 513), otherwise the meta-data is discarded (step 511).

It should be noted that in alternate embodiments of the present invention, meta-data related to the user's capabilities and/or viewing habits may be retrieved from database 407, with all meta-data for programs relevant to the user's capabilities and viewing habits stored locally in database 403. Meta-data for programs relevant to the user's viewing habits include such things as meta-data for frequently-watched programs, while meta-data for programs related to the user's capabilities include meta-data for programs actually capable of being viewed by remote unit 300.

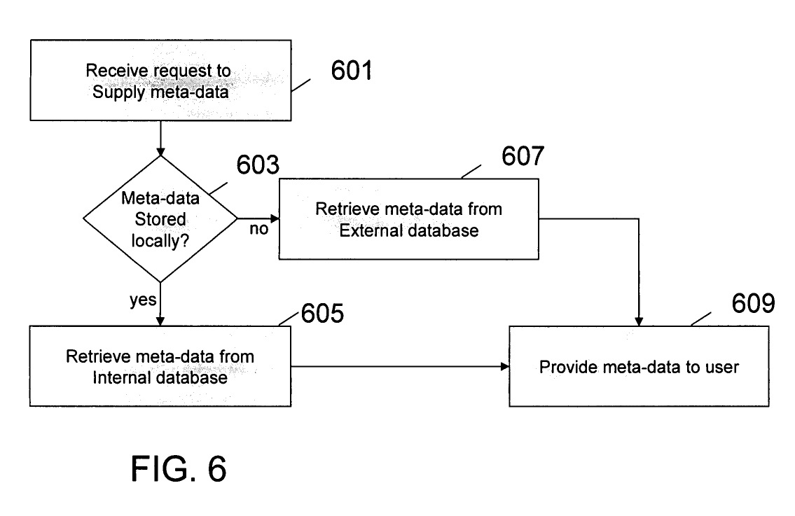

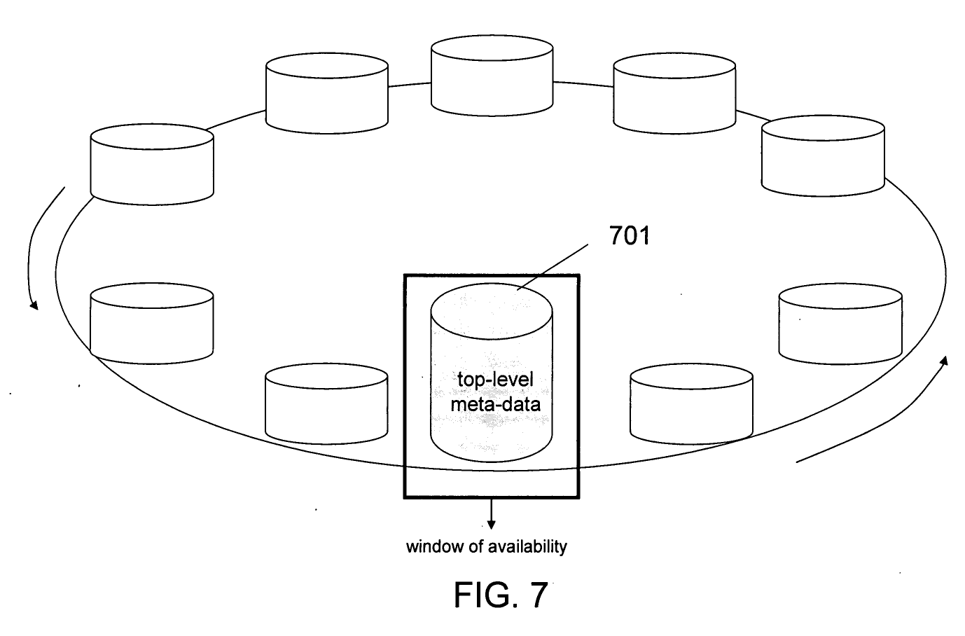

As discussed above, because only selective data is stored locally, remote unit 300 has the ability to store meta-data that is likely to be retrieved by the user, while discarding all other meta-data. The stored data can be accessed very quickly when requested. If, however, meta-data is requested that does not exist in database 403, the data can be accessed through carousel 200. A flow chart showing this procedure is detailed in FIG. 6.

FIG. 6 is a flow chart showing operation of the remote unit of FIG. 4 for retrieving meta-data. The logic flow begins at step 601 where a request to supply meta-data is received by logic circuitry 409. At step 603, logic circuitry accesses database 403 to determine if the requested meta-data is stored locally. If, at step 603 it is determined that the requested meta-data is within database 403, the logic flow continues to step 605, otherwise the logic flow continues to step 607.

At step 605 the requested meta-data is retrieved from database 403, and at step 609 the meta-data is provided to the user. In a similar manner, at step 607 the meta-data is retrieved from an external database (e.g., carousel 200) and at step 609 the metadata is provided to the user.

While the invention has been particularly shown and described with reference to a particular embodiment, it will be understood by those skilled in the art that various changes in form and details may be made therein without departing from the spirit and scope of the invention. For example, the user preferences capabilities database 407 may be available outside the device, as in a remote server accessible to the device, rather than being on the device itself, or the entire process illustrated in FIG. 4 may be carried out without user intervention of an EPG, using instead an intelligent agent, running on top of the logic circuitry 409, in order to provide unassisted recording of programs which may be of interest to a user, as in an intelligent Personal Video Recorder system, among other alternatives. It is intended that such changes come within the scope of the following claims.

While the invention has been particularly shown and described with reference to a particular embodiment, it will be understood by those skilled in the art that various changes in form and details may be made therein without departing from the spirit and scope of the invention. For example, in the preferred embodiment described above, each container in the carousel is fully decoded and if its payload is relevant when matched against the user preferences, the meta-data is stored locally in database 403. This is the case for meta-data formats where the top-level meta-data can be distributed throughout the carousel and can be placed at the header of each container. However, for certain meta-data formats, relevant meta-data cannot be carried at the top of the meta-data hierarchy. In such cases, one container in the carousel may be set up to carry all the top-level meta-data for all containers in the carousel, as well as an index indicating the ID number of the carousel carrying each fragment of meta-data, as depicted in FIG. 7. This container can be considered an “index” for the meta-data stored in the other containers.

When the “index” container 701 is transmitted over the air and retrieved by receiver 413, it is then decoded and compared against the personal preferences database 407. Only the meta-data entries matching the preferences stored in database 407 are then stored in database 403. Database 403 will then contain all the matching high-level meta-data carried in all containers and an index pointing at the container where each particular meta-data entry is located. During a typical decoding process, when a container arrives at the “window of availability” 201, its ID is compared against those in database 403 and if the ID of the container being processed appears in database 403, then the container is further analyzed, following one of two alternate embodiments. In the first alternate embodiment, the container is decoded in full and only the fragments matching the personal preference database 407 are stored in database 403. In the second alternate embodiment, the container is not decoded in full, but rather it is stored in local memory in compressed form. The stored containers are decoded and stored in database 403 only when the user requests them. It is intended that such changes come within the scope of the following claims.

1. A method for meta-data storage, the method comprising the steps of:
receiving meta-data from an external source;
determining if the meta-data is essential to a formation of an electronic programming guide (EPG);
determining if the meta-data is relevant to a user's preferred programs;
storing the meta-data that is essential to the formation of the EPG;
storing the meta-data that is relevant to the user's preferred programs; and
discarding all other meta-data.

2. The method of claim 1 wherein the step of receiving the meta-data comprises the step of receiving the meta-data via an over-the-air transmission.

3. The method of claim 1 wherein the step of determining if the meta-data is essential to the formation of the EPG comprises the step of determining if the meta-data comprises meta-data taken from the group consisting of meta-data of program names, meta-data of program times, meta-data of program lengths, meta-data of program genres, meta-data of program languages, meta-data of parental ratings, and meta-data of program cost.

4. The method of claim 1 wherein the step of determining if the meta-data is relevant to the user's preferred programs comprises the step of determining if the meta-data comprises meta-data taken from the group consisting of the user's preferred genre and sub-genre, the user's preferred actors, and the user's preferred language.

5. The method of claim 1 further comprising the steps of:
determining if the meta-data is relevant to the user's viewing habits; and
storing the meta-data that is relevant to the user's habits.

6. The method of claim 5 wherein the step of determining if the meta-data is relevant to the user's habits comprises the step of determining if the meta-data comprises meta-data for frequently-watched programs.

7. The method of claim 1 further comprising the steps of:
determining if the meta-data is relevant to the user's capabilities; and
storing the meta-data that is relevant to the user's capabilities.

8. The method claim 7 wherein the step of determining if the meta-data is relevant to the user's capabilities comprises the step of determining if the meta-data is for programs capable of being watched by the user.

9. The method of claim 1 further comprising the steps of:
determining if the meta-data is relevant to the user's habits;
storing the meta-data that is relevant to the user's habits;
determining if the meta-data is relevant to the user's capabilities; and
storing the meta-data that is relevant to the user's capabilities.

10. A method comprising the steps of:
retrieving a request to supply meta-data to a user;
determining if the meta-data resides in a local database, wherein the local database comprises meta-data that is relevant to the user's preferred programs and meta-data that is essential to a formation of an electronic programming guide (EPG); and
retrieving the meta-data from the local database when the meta-data resides in the local database otherwise retrieving the meta-data from an external database.

11. The method of claim 10 wherein the local database additionally comprises meta-data is relevant to the user's habits.

12. The method of claim 10 wherein the local database additionally comprises meta-data is relevant to the user's capabilities.

13. The method of claim 10 wherein the step of retrieving the meta-data from the local database when the meta-data resides in the local database otherwise retrieving the meta-data from the external database comprises the step of retrieving the meta-data from the local database when the meta-data resides in the local database otherwise retrieving the meta-data over-the-air from the external database.

14. An apparatus comprising:
a receiver having as an input, meta-data received from an external source;
logic circuitry determining if the meta-data is essential to a formation of an electronic programming guide (EPG) or relevant to a user's preferred programs; and
a database storing the meta-data that is essential to the formation of the EPG and the meta-data that is relevant to the user's preferred programs.

15. The apparatus of claim 14 wherein the receiver receives the meta-data via an over-the-air transmission.

16. The apparatus of claim 14 wherein meta-data essential to the formation of the EPG comprises meta-data taken from the group consisting of meta-data of program names, meta-data of program times, meta-data of program lengths, meta-data of program genres, meta-data of program languages, meta-data of parental ratings, and meta-data of program cost.

17. The apparatus of claim 14 wherein the meta-data relevant to the user's preferred programs comprises meta-data taken from the group consisting of the meta-data on programs having the user's preferred genre and sub-genre, meta-data on programs having the user's preferred actors, and meta-data on programs having the user's preferred language.

18. An apparatus comprising:
a local database; and
logic circuitry retrieving a request to supply meta-data to a user and determining if the meta-data resides in the local database, wherein the local database comprises meta-data that is relevant to the user's preferred programs and meta-data that is essential to a formation of an electronic programming guide (EPG), wherein the logic circuitry, when requested, retrieves the meta-data from the local database when the meta-data resides in the local database otherwise retrieves the meta-data from an external database.

19. The apparatus of claim 18 wherein the local database additionally comprises meta-data for programs relevant to a user's viewing habits.

20. The apparatus of claim 18 wherein the local database additionally comprises meta-data for programs capable of being viewed by the user.

21. The apparatus of claim 18 further comprising:
a second local database populated with the meta-data that is relevant to the user's preferred programs.

22. The apparatus of claim 21 wherein the second local database is populated by analyzing meta-data currently accessed by the user and storing the meta-data.

23. The apparatus of claim 21 wherein meta-data is removed from the second local database when a period of validity is exceeded.
